(19) United States
(12) Patent Application Publication
(10) Pub. No.: US 2009/0154092 A1
(43) Pub. Date: Jun. 18, 2009

(54) WIND DIRECTION-ADJUSTABLE HEAT-DISSIPATION FAN MODULE

(76) Inventor: Michael CHEN, Taipei Hsien (TW)

Correspondence Address: Joe McKinney Muncy, PO Box 1364, Fairfax, VA, 22038-1364, US

(21) Appl. No.: 11/959,175

(22) Filed: Dec. 18, 2007

(51) Int. Cl. H05K 7/20

(52) U.S. Cl. 361/679.51

(57) ABSTRACT

The present invention discloses a wind direction-adjustable heat-dissipation fan module, which is arranged inside a computer and provides heat-dissipation air current for electronic devices inside the computer. The wind direction-adjustable heat-dissipation fan module of the present invention comprises a support unit arranged inside the computer. An electric fan is pivotally coupled to the support unit, and the electric fan can have a rotation trip with respect to the support unit. According to the layout of the electronic devices inside the computer, the electric fan can be rotated pivotally with respect to the support unit to adjust the angle of the wind outlet. The present invention can solve the incapability of the conventional heat-dissipation fan to adjust the angle thereof, which causes inferior heat-dissipation inside a computer.

### FIELD OF THE INVENTION

The present invention relates to a wind direction-adjustable heat-dissipation fan module, particularly to a wind direction-adjustable heat-dissipation fan module, which is installed inside a computer, wherein the position and direction of the heat-dissipation fan can be adjusted to provide appropriate air current for the electronic devices inside the computer.

### BACKGROUND OF THE INVENTION

There are various electronic devices installed inside a computer, such as hard drives, CPU, power supplies, PCBs having many electronic elements thereon, etc. Those electronic devices generate a great amount of heat during operation. Thus, heat-dissipation fans are used to keep the electronic devices working at an appropriate temperature. Generally, a heat-dissipation fan is arranged in the front or rear side of a computer to suck in external cool air and expel hot air inside the computer so that the temperature of the electronic devices can be cooled down.

The abovementioned fixed type heat-dissipation fan arranged in the front or rear side of a computer cannot be adjusted to provide air current with a specified wind direction for a specified area inside the computer but can only provide air current of a fixed wind direction. The number of the electronic devices inside a computer is fast increasing, and the working efficiency thereof (such as the rotation speed or the processing speed) is also greatly upgraded, which results in that the working temperature rises obviously. The fixed type heat-dissipation fans have been hard to meet the need. Therefore, the related manufacturers developed position-adjustable heat-dissipation fans. A R.O.C. patent publication No. 526958 disclosed a “Mobile Heat-Dissipation Device”, which comprises: a fixing clamp seat and a moveable plate pivotally installed in the fixing clamp seat. The moveable plate has a rail to mount at least one electric fan. The electric fan can slide on the rail of the moveable plate, and the moveable plate can pivotally rotate with respect to the fixing clamp seat. Thereby, the wind direction of the electric fan can be adjusted. However, the mobile heat-dissipation device is installed in the motherboard, and the movement field of the electric fan is likely to be limited by the electronic devices on the motherboard (such as CPU, memories, etc.), which disadvantages the heat-dissipation effect of the conventional technology.

A R.O.C. patent publication No. 1265778 disclosed an “Electric Fan Assembly”, which comprises: an auxiliary fixing element and an electric fan. The auxiliary fixing element has a fixing member used to couple with an object and a connection member extending from one end of the fixing member. The connection member has at least one insertion portion to receive the electric fan. The wind direction of the electric fan can be adjusted via inserting the electric fan into different insertion portions of the connection member. The conventional technology can indeed adjust the wind direction of the electric fan. However, the position of the electric fan cannot be arranged according to the layout of the electronic devices inside a computer but is limited by the insertion portions of the connection member.

### SUMMARY OF THE INVENTION

The primary objective of the present invention is to provide a wind direction-adjustable heat-dissipation fan module to solve the abovementioned problems, wherein the angle of the electric fan is adjusted to orient the wind outlet toward the electronic devices needing heat dissipation, whereby the heat-dissipation quality of a computer can be promoted.

To achieve the abovementioned objective, the present invention proposes a wind direction-adjustable heat-dissipation fan module, which comprises a support unit arranged inside a computer. An electric fan is pivotally installed in the support unit, and the electric fan can have a rotation trip with respect to the support unit. According to the layout of the electronic devices inside the computer, the electric fan can be rotated pivotally with respect to the support unit to adjust the angle of the wind outlet to attain better heat-dissipation efficiency.

### BRIEF DESCRIPTION OF THE DRAWINGS

FIG. 1 is a perspective view of the present invention.

FIG. 2 is an exploded view of the present invention.

FIG. 3 is a side view of the present invention.

FIG. 4 is a diagram schematically showing an application case of the present invention.

FIG. 5 is a diagram schematically showing another application case of the present invention.

FIG. 6A to FIG. 6C are diagrams schematically showing the embodiments of the present invention.

### DETAILED DESCRIPTION OF THE PREFERRED EMBODIMENTS

Below, the technical contents of the present invention will be described in detail in cooperation with the drawings.

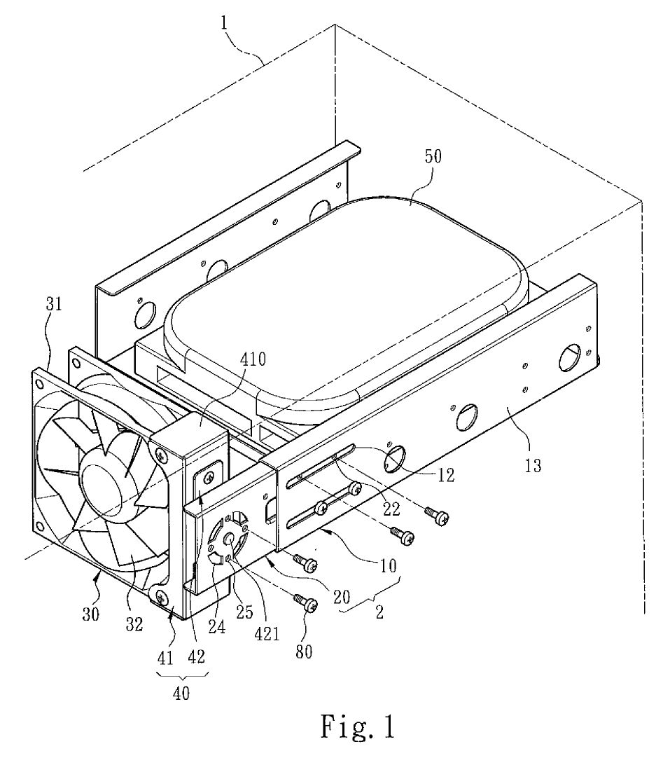

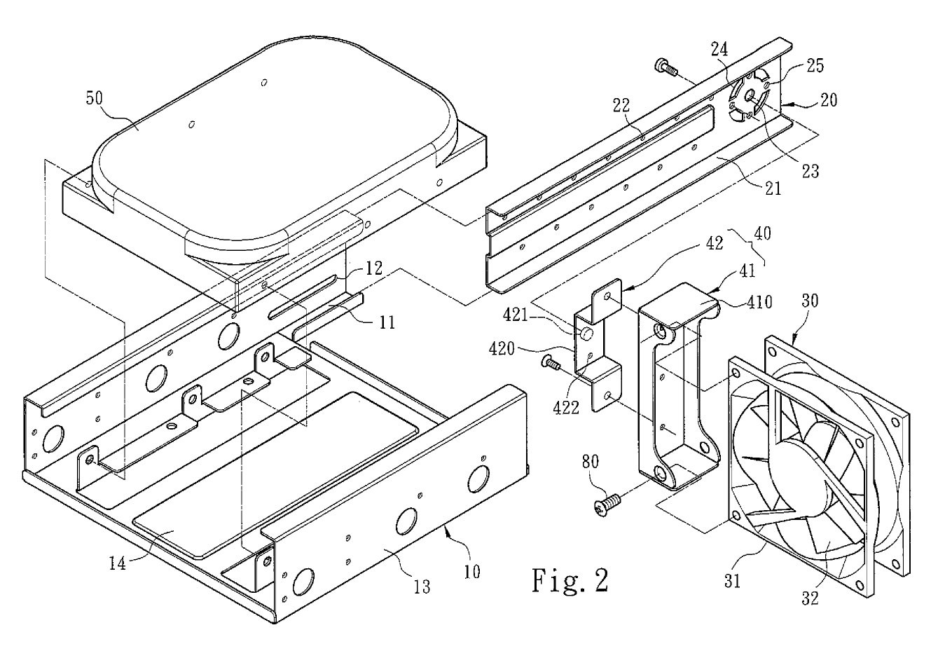

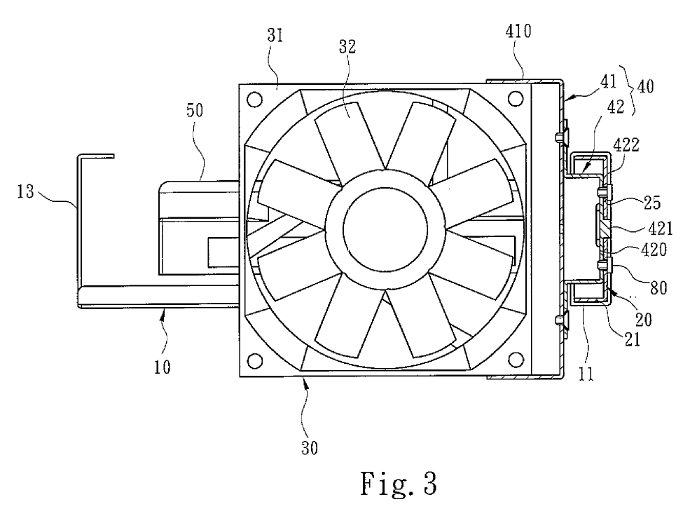

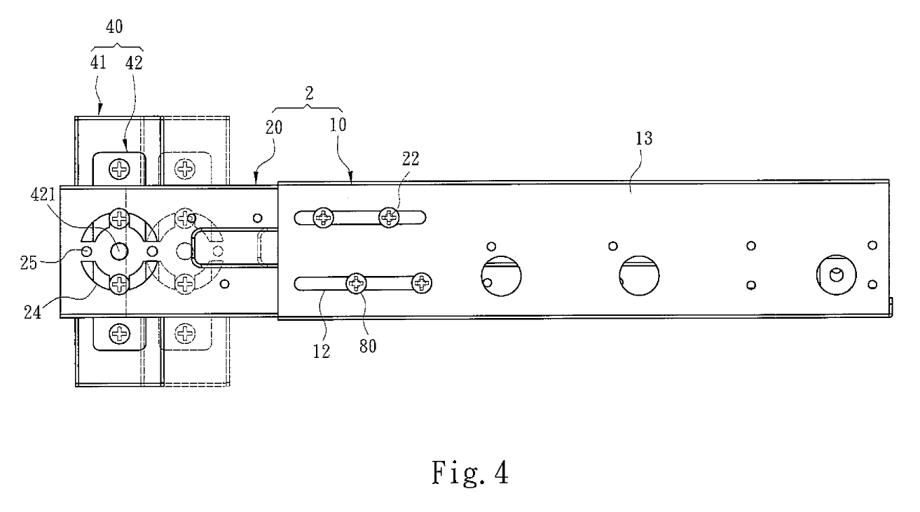

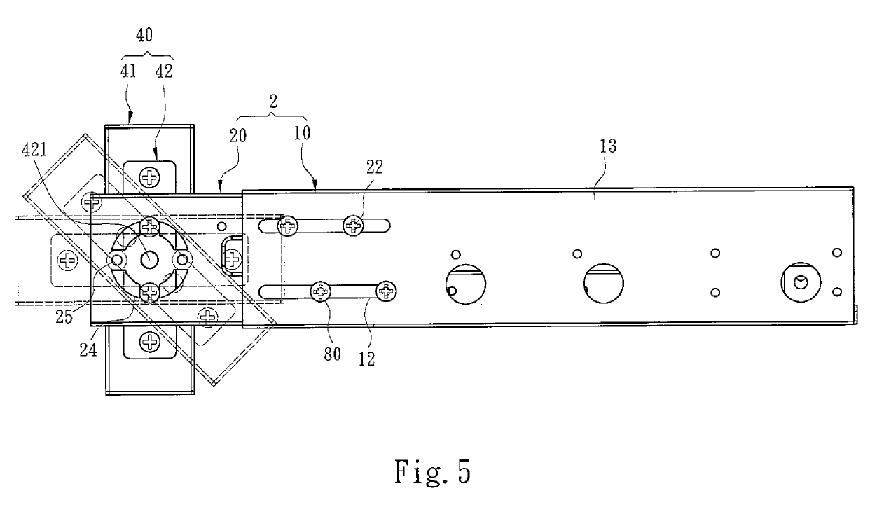

Refer to FIG. 1, FIG. 2 and FIG. 3. The present invention proposes a wind direction-adjustable heat-dissipation fan module, which comprises a support unit 2 arranged inside a computer 1. An electric fan 30 is pivotally installed in the support unit 2, and the electric fan 30 has a rotation trip with respect to the support unit 2 for adjusting the angle of the wind outlet. In the present invention, the support unit 2 has a fixed frame 10 arranged inside the computer 1 and at least one moveable frame 20 installed in the fixed frame 10, wherein the electric fan 30 is pivotally installed in the moveable frame 20. The fixed frame 10 has a slide rail 11, and the moveable frame 20 has a slide member 21 corresponding to the slide rail 11. Via the slide rail 11 and the slide member 21, the moveable frame 20 can have a translation trip with respect to the fixed frame 10. Thereby, the horizontal position of the electric fan 30 can be adjusted, as shown in FIG. 4. The fixed frame 10 has position-adjusting slots 12, and the moveable frame 20 has position-fixing holes 22. The moveable frame 20 is moved to an appropriate position, and position-fixing elements 80 are then inserted through the position-adjusting slots 12 and the position-fixing holes 22 to fasten the moveable frame 20 to the fixed frame 10. The electric fan 30 has a fan casing 31 and fan blades 32 accommodated by the fan casing 31. The fan casing 31 is pivotally installed in the moveable frame 20 of the support unit 2 via a pivotal-rotation mechanism 40. The electric fan 30 and the pivotal-rotation mechanism 40 can be fabricated into a one-piece component. The pivotal-rotation mechanism 40 includes: a connection member 41, which is assembled to the fan casing 31 of the electric fan 30, and a pivotal-rotation member 42, which is coupled to the connection member 41 and pivotally installed in the moveable frame 20. The connection member 41 has two wing portions 410 used to fixedly hold the fan casing 31 and take the electric fan 30 to rotate. The pivotal-rotation member 42 has a pivotal-rotation portion 420, and the pivotal-rotation portion 420 has a pivotal axis 421. The pivotal axis 421 is pivotally coupled to an axis hole 23 of the moveable frame 20. The rotation of the pivotal-rotation member 42 with respect to the moveable frame 20 drives the connection member 41 and the electric fan 30 to rotate. Thereby, the angle and wind direction of the electric fan 30 can be adjusted, as shown in FIG. 5. The pivotal-rotation portion 420 has position-fixing holes 422, and the moveable frame 20 has angle-adjusting holes 24 corresponding to the position-fixing holes 422. The pivotal-rotation member 42 is rotated to an appropriate angle, and position-fixing elements 80 are then inserted through the angle-adjusting holes 24 and the position-fixing holes 422 to fasten the pivotal-rotation member 42 to the moveable frame 20. The angle-adjusting holes 24 include special-angle holes 25. Each special-angle hole 25 is formed in between each two angle-adjusting holes 24, and each two special-angle holes 25 are separated by a special angle along the rotation path of the pivotal-rotation member 42. Via the special-angle holes 25, the electric fan may have a special angle, such as an angle of 90 or 180 degrees. Thus is completed a wind direction-adjustable heat-dissipation fan module, wherein the position and angle of the electric fan 30 can be adjusted to provide appropriate heat-dissipation air current for electronic devices 50 inside the computer 1. In this embodiment, the electric fan 30 may be an axial flow fan or a centrifugal fan.

In the present invention, the support unit 2 comprises at least one support arm 13 fixedly connected with the computer 1. In this embodiment, the support unit 2 comprises: two support arms 13 and a support board 14, and an assembly space, which accommodates electronic devices 50, is formed on the support unit 2. Pivotally coupling the electric fan 30 to only one support arm 13 is enough to attain a rotation trip. For efficiently utilizing the space inside the computer 1, the residual space of the support unit 2 can be used to accommodate electronic devices 50, such as hard drives and optical drives.

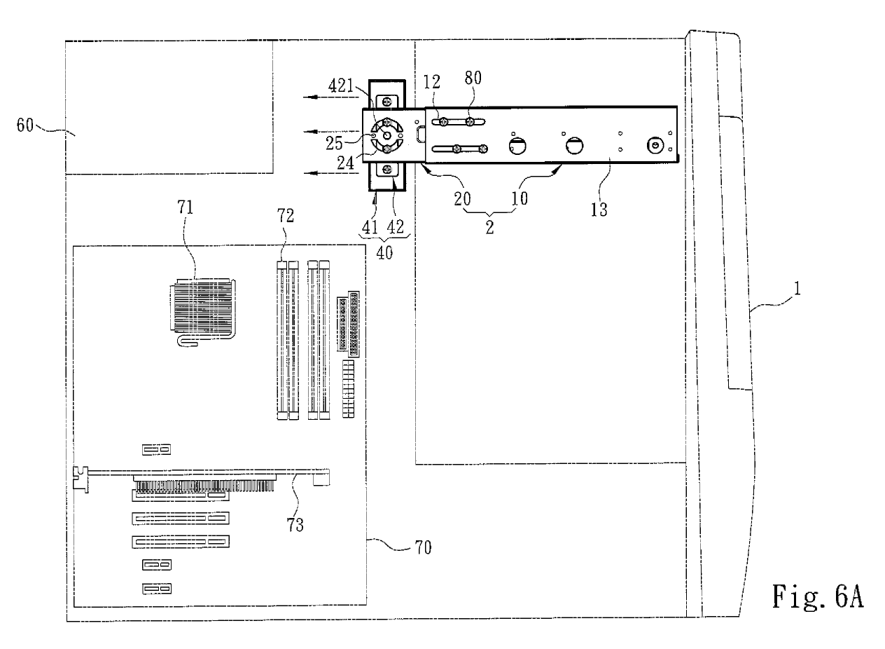

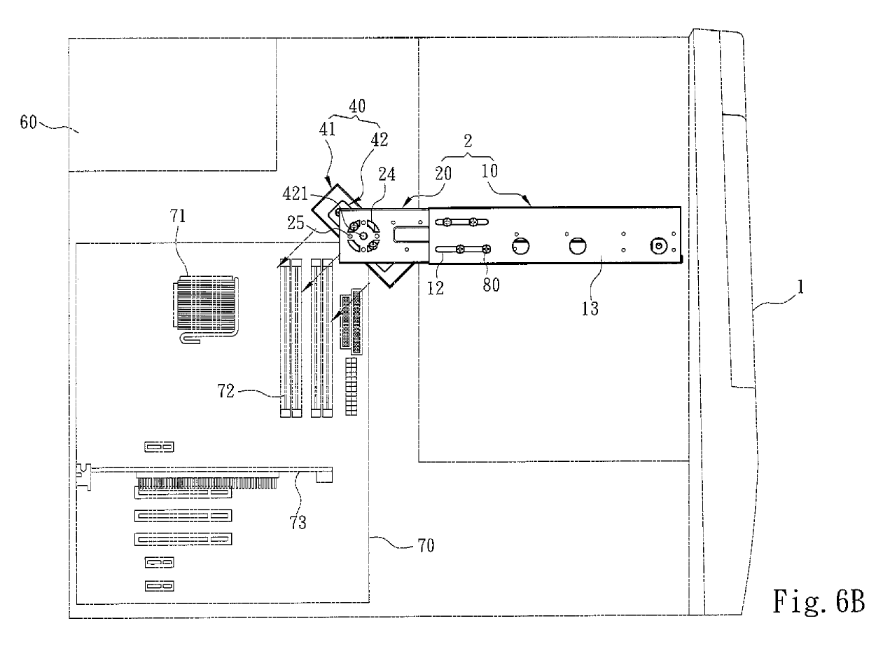

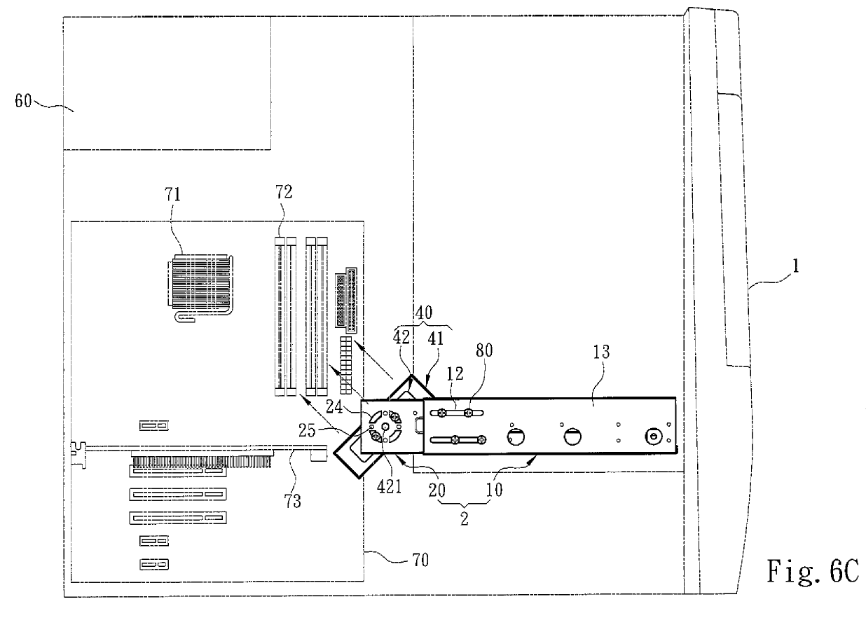

Refer to FIG. 6A. The support unit 2 is arranged in the topmost layer of the computer 1, and the wind outlet is oriented toward a power supply 60. When the electric fan 30 is turned on, the hot air around the electronic devices 50 is sucked out to keep the electronic devices 50 working at an appropriate temperature. The electric fan 30 also dissipates the heat of the power supply 60, and the hot air is them expelled out of the computer via the power supply 60. Refer to FIG. 6B. The support unit 2 is arranged in another layer of the computer 1, and the electric fan 30 is oriented toward electronic devices on a motherboard 70 (such as CPU 71, memories 72 and a display card 73 shown in the drawings), and the wind direction is thus changed to provide a heat-dissipation environment for the abovementioned electronic devices. Refer to FIG. 6C. The support unit 2 is arranged in the bottommost layer of the computer 1, and the electric fan 30 is oriented toward the rear-side heat-dissipation holes or electric fan (not shown in the drawings) to integrate the heat-dissipation devices inside the computer 1 and expel the hot air inside the computer 1 all together.

Besides the embodiments described above, the user can also arbitrarily adjusts the position and angle of the electric fan 30 to provide appropriate heat-dissipation environments for different layouts of the electronic devices inside the computer 1. The preferred embodiments described above are only to exemplify the present invention but not to limit the scope of the present invention. Any equivalent modification or variation according to the spirit of the present invention is to be also included within the scope of the present invention.

What is claimed is:

1. A wind direction-adjustable heat-dissipation fan module, wherein the angle of an electric fan is adjusted to change the wind direction thereof and provide appropriate heat-dissipation air current for electronic devices inside a computer, characterized in
that said wind direction-adjustable heat-dissipation fan module comprises a support unit arranged inside said computer, and
that said electric fan is pivotally coupled to said support unit and has a rotation trip with respect to said support unit.

2. The wind direction-adjustable heat-dissipation fan module according to claim 1, wherein said support unit further comprises at least one support arm fixedly connected with said computer.

3. The wind direction-adjustable heat-dissipation fan module according to claim 2, wherein said support unit includes: two support arms and a support board, and an assembly space, which accommodates electronic devices, is formed on said support unit.

4. The wind direction-adjustable heat-dissipation fan module according to claim 1, wherein said electric fan further comprises: a fan casing and fan blades accommodated by said fan casing; said fan casing has a pivotal-rotation mechanism to pivotally connect with said support unit.

5. The wind direction-adjustable heat-dissipation fan module according to claim 1, wherein said support unit further comprises: a fixed frame arranged inside said computer and at least one moveable frame installed in said fixed frame; said moveable frame has a translation trip with respect to said fixed frame, and said electric fan is pivotally coupled to said moveable frame.

6. The wind direction-adjustable heat-dissipation fan module according to claim 5, wherein said fixed frame has a slide rail, and said moveable frame has a slide member corresponding to said slide rail, and said translation trip is realized with said slide rail and said slide member.

7. The wind direction-adjustable heat-dissipation fan module according to claim 5, wherein said fixed frame has position-adjusting slots, and said moveable frame has position-fixing holes; during said translation trip, position-fixing elements are inserted through said position-adjusting slots and said position-fixing holes to fasten said moveable frame to said fixed frame.

8. The wind direction-adjustable heat-dissipation fan module according to claim 5, wherein said electric fan further comprises: a fan casing and fan blades accommodated by said fan casing; said fan casing has a pivotal-rotation mechanism to pivotally connect with said support unit.

9. The wind direction-adjustable heat-dissipation fan module according to claim 8, wherein said electric fan and said pivotal-rotation mechanism are fabricated into a one-piece component.

10. The wind direction-adjustable heat-dissipation fan module according to claim 8, wherein said pivotal-rotation mechanism includes: a connection member, which is assembled to said fan casing, and a pivotal-rotation member, which is coupled to said connection member and pivotally installed in said moveable frame.

11. The wind direction-adjustable heat-dissipation fan module according to claim 10, wherein said connection member has two wing portions used to fixedly hold said fan casing and take said electric fan to generate said rotation trip.

12. The wind direction-adjustable heat-dissipation fan module according to claim 10, wherein said pivotal-rotation member has a pivotal-rotation portion, and said pivotal-rotation portion has a pivotal axis; said pivotal axis is pivotally coupled to an axis hole of said moveable frame.

13. The wind direction-adjustable heat-dissipation fan module according to claim 12, wherein said pivotal-rotation portion has position-fixing holes, and said moveable frame has angle-adjusting holes corresponding to said position-fixing holes; said pivotal-rotation member is rotated to an appropriate angle, and position-fixing elements are then inserted through said angle-adjusting holes and said position-fixing holes to fasten said pivotal-rotation member to said moveable frame.

14. The wind direction-adjustable heat-dissipation fan module according to claim 13, wherein said angle-adjusting holes include special-angle holes; each said special-angle hole is formed in between each two said angle-adjusting holes, and each two said special-angle holes are separated by a special angle along the rotation path of said pivotal-rotation member.

15. The wind direction-adjustable heat-dissipation fan module according to claim 1, wherein said electric fan is an axial flow fan.

16. The wind direction-adjustable heat-dissipation fan module according to claim 1, wherein said electric fan is a centrifugal fan.
